(19) United States
(12) Patent Application Publication
(10) Pub. No.: US 2012/0326119 A1
(43) Pub. Date: Dec. 27, 2012

(54) LIGHT EMITTING DISPLAY DEVICE HAVING NANOWIRE

(75) Inventors: Sang Hyun Ju, Gyeonggi-do (KR); Mi Sook Suh, Gyeonggi-do (KR)

(73) Assignee: Kyonggi University Industry & Academia Cooperation Foundation, Gyeonggi-do (KR)

(21) Appl. No.: 13/582,039

(22) PCT Filed: Mar. 2, 2011
(86) PCT No.: PCT/KR2011/001421

§ 371 Date: Aug. 30, 2012

(30) Foreign Application Priority Data
Mar. 8, 2010 (KR) 10-2010-0020201
Mar. 8, 2010 (KR) 10-2010-0020202

(51) Int. Cl. H01L 33/06; B82Y 99/00

(52) U.S. Cl. 257/13; 257/E33.006; 977/952

(57) ABSTRACT

The invention is a light emitting display device having a nanowire that emits light when an electric current is applied. The disclosed light emitting display device comprises: a nanowire light emitting element electrically connected to a first power line; a driving transistor electrically connected between the light emitting element and a second power line; a capacitor electrically connected between the driving transistor, the second power line, and a data line; and a switching transistor electrically connected between the driving transistor, the data line, and a scanning line. The invention discloses a light emitting display device comprising: a nanowire light emitting transistor electrically connected between a first power line and a second power line; a capacitor electrically connected between the nanowire light emitting transistor, second power line, and a data line; and a switching transistor electrically connected between the nanowire light emitting transistor, data line, capacitor, and a scanning line.

### TECHNICAL FIELD

One embodiment of the present invention relates to a light emitting display device having a nanowire.

### BACKGROUND ART

Since a liquid display device, which has been widely utilized as a main flat display device, does not employ a self-light emitting element, an additional light emitting element such as a backlight is required for the liquid display device. Due to the above structure, the liquid display has a limit on a thickness or a simplified structure.

Since an active matrix organic light emitting device (AMOLED) conceived to overcome the above limitation of the liquid crystal display device employs a self-emissive organic light emitting device, a backlight or a color filter is not required. Due to the above, the active matrix organic light emitting device has a simple structure and has a high-light extracting efficiency.

In spite of the above advantages of the self-light emitting element, due to the material limitation, it is difficult to employ an AMOLED up to now. Due to a characteristic of the material which is vulnerable to moisture, an encapsulation process should be necessary and there is no specific process for fabricating the element other than a vacuum deposition process. In order to overcome the above limitation, material has been expanded to the high-molecular material and another method such as an inkjet method, a laser induced thermal imaging (LITI) method and the like has been founded, however, a method which satisfies a characteristic and a lifetime of the element has not been generalized.

### DISCLOSURE

### Technical Problem

A technical solution to be achieved by one embodiment of the present invention is to provide a light emitting display device having a nanowire light emitting element in which a nanowire is formed between the electrodes having different work functions to emit the light when a current is applied to the nanowire.

A technical solution to be achieved by another embodiment of the present invention is to provide a light emitting display device having a nanowire light emitting element in which a light emitting element as well as a transistor and a capacitor are fabricated with a nanowire to enable a fabricating process to be simplified.

A technical solution to be achieved by yet another embodiment of the present invention is to provide a light emitting display device having a nanowire light emitting element employing a nanowire light emitting transistor having a function of semiconductor and a light emitting function to simplify a fabricating process and increase a light-emitting region in comparison with a driving circuit section.

### Technical Solution

The light emitting display device according to the present invention comprises a light emitting element electrically connected to a first power line; a driving transistor electrically connected to the light emitting element and a second power line; a capacitor electrically connected to the driving transistor, the second power line and a data line; and a switching transistor electrically connected among the driving transistor, the data line, and a scanning line. Here, the light emitting element is made from a nanowire.

The light emitting element further comprises a first electrode covering one end of the nanowire and inner circumference and outer circumference surfaces of the one end and electrically connected to the first power line; and a second electrode covering the other end of the nanowire and inner circumference and outer circumference surfaces of the other end and electrically connected to the second power line. Here, the first electrode has the work function which differs from that of the second electrode. The first electrode is flush with the second electrode and spaced apart from the second electrode in the horizontal direction.

The light emitting element further comprises a first electrode formed below the nanowire; and a second electrode formed above the nanowire. Here, the work function of the first electrode differs from that of the second electrode. The first electrode is not flush with the second electrode and spaced apart from the second electrode in the vertical direction.

The light emitting element comprises at least one first electrode; and a second electrode spaced apart from the first electrode in the horizontal direction and surrounding at least three side surfaces of the first electrode, and the nanowire is formed between the first electrode and the second electrode. Here, the work function of the first electrode differs from that of the second electrode. A color filter is further formed on or below the light emitting element.

The driving transistor or the switching transistor comprises a gate electrode; a gate insulating layer covering the gate electrode; a second nanowire formed on the gate insulating layer corresponding to the gate electrode; a first electrode connected to one end of the second nanowire; and a second electrode connected to the other end of the second nanowire.

The driving transistor or the switching transistor comprises a second nanowire; a gate insulating layer covering the second nanowire; a gate electrode formed on the gate insulating layer corresponding to the second nanowire; an interlayer dielectric covering the gate electrode and the gate insulating layer corresponding to a periphery the gate electrode; a first electrode penetrating the interlayer dielectric and connected to one end of the second nanowire; and a second electrode penetrating the interlayer dielectric and connected to the other end of the second nanowire.

The driving transistor or the switching transistor comprises a second nanowire; a first electrode connected to one end of the second nanowire; a second electrode connected to the other end of the second nanowire; a gate insulating layer covering the second nanowire, the first electrode and the second electrode; and a gate electrode formed on the gate insulating layer corresponding to the second nanowire.

The capacitor comprises a second nanowire formed on a substrate; an insulating layer surrounding the second nanowire; a first electrode surrounding the insulating layer; and a second electrode connected to the second nanowire exposed through the insulating layer. A recess is formed on an area of the substrate corresponding to the insulator.

The capacitor comprises a second nanowire; a first electrode connected to the second nanowire; an insulating layer covering the second nanowire; and a second electrode formed on the insulating layer corresponding to the second nanowire.

The nanowire is formed of mixture or compound of CaS:Eu, ZnS:Sm, ZnS:Mn, Y₂O₂S :Eu, Y₂O₂S :Eu,Bi, Gd₂O₃ :Eu, (Sr,Ca,Ba,Mg)P₂O₇:Eu,Mn, CaLa₂S₄:Ce, SrY₂S₄:Eu, (Ca,Sr)S:Eu, SrS:Eu, Y₂O₃:Eu, YVO₄:Eu,Bi, ZnS:Tb, ZnS:Ce,Cl, ZnS:Cu,Al, Gd₂O₂S:Tb, Gd₂O₃:Tb,Zn, Y₂O₃:Tb,Zn, SrGa₂S₄:Eu, Y₂SiO₅:Tb, Y₂Si₂O₇:Tb, Y₂O₂S:Tb, ZnO:Ag, ZnO:Cu,Ga, CdS:Mn, BaMgAl₁₀O₁₇:Eu,Mn, (Sr,Ca,Ba)(Al,Ga)2S₄:Eu, Ca₈Mg(SiO₄)4Cl₂:Eu,Mn, YBO₃:Ce,Tb, Ba₂SiO₄:Eu, (Ba,Sr)2SiO₄:Eu, Ba₂(Mg,Zn)Si₂O₇:Eu, (Ba,Sr)Al₂O₄:Eu, Sr₂Si₃O₈,2SrCl₂:Eu, SrS:Ce, ZnS:Tm, ZnS:Ag,Cl, ZnS:Te, Zn₂SiO₄:Mn, YSiO₅:Ce, (Sr,Mg,Ca)10(PO₄)6Cl₂:Eu, BaMgAl₁₀O₁₇:Eu, BaMg₂Al₁₆O₂₇:Eu, YAG (yttrium, alumium, garnet) or mixture or compound utilizing CaxSrx-1Al₂O₃:Eu+2 obtained by synthesizing CaAl₂O₃ and SrAl₂O₃ , or any one selected from the group consisting of ZnO, In₂O₃, SnO₂, SiGe, GaN, InP, InAs, Ge, GaP, GaAs, GaAs/P, InAs/P, ZnS, ZnSe, CdS, CdSe or mixture or compound thereof. A dopant which is any one selected from the group consisting of Ce, Tm, Ag, Cl, Te, Mn, Eu, Bi, Tb, Cu, Zn, Ga or mixture or compound thereof may be further added to the nanowire.

The second nanowire is formed of any one selected from the group consisting of ZnO, In₂O₃, SnO₂, SiGe, GaN, InP, InAs, Ge, GaP, GaAs, GaAs/P, InAs/P, ZnS, ZnSe, CdS, CdSe or mixture or compound thereof. A dopant which is any one selected from the group consisting of Ce, Tm, Ag, Cl, Te, Mn, Eu, Bi, Tb, Cu, Zn, Ga or mixture or compound thereof may be further added.

The first and second electrodes of the driving transistor or the switching transistor have the same work function. Otherwise, the work function of the first electrode of the driving transistor or the switching transistor differs from that of the second electrode, and a light shielding member is further formed on or below the driving transistor or the switching transistor.

The light emitting display device according to one embodiment of the present invention comprises a nanowire light emitting transistor electrically connected to a first power line and a second power line; a capacitor electrically connected to the nanowire light emitting transistor, the second power line and a data line; and a switching transistor electrically connected to the nanowire light emitting transistor, the data line, the capacitor and a scanning line.

The nanowire light emitting transistor comprises a gate electrode; a gate insulating layer covering the gate electrode; a nanowire formed on the gate insulating layer corresponding to the gate electrode; a first electrode connected to one end of the nanowire; and a first electrode connected to the other end of the nanowire. Here, a work function of the first electrode differs from that of the second electrode.

The nanowire light emitting transistor comprises a nanowire; a gate insulating layer covering the nanowire; a gate electrode formed on the gate insulating layer corresponding to the nanaowire; an interlayer dielectric covering the gate electrode and the gate insulating layer corresponding to a periphery the gate electrode; a first electrode penetrating the interlayer dielectric and connected to one end of the nanowire; and a second electrode penetrating the interlayer dielectric and connected to the other end of the nanowire. Here, a work function of the first electrode differs from that of the second electrode.

The nanowire light emitting transistor comprises a nanowire; a first electrode connected to one end of the nanowire; a second electrode connected to the other end of the nanowire; a gate insulating layer covering the nanowire, the first and second electrodes; and a gate electrode formed on the gate insulating layer corresponding to the nanowire. Here, a work function of the first electrode differs from that of the second electrode.

The switching transistor comprises a gate electrode; a gate insulating layer covering the gate electrode; a nanowire formed on the gate insulating layer corresponding to the gate electrode; a first electrode connected to one end of the nanowire; and a second electrode connected to the other end of the nanowire.

The switching transistor comprises a nanowire; a gate insulating layer covering the nanowire; a gate electrode formed on the gate insulating layer corresponding to the nanowire; an interlayer dielectric covering the gate electrode and the gate insulating layer corresponding to a periphery the gate electrode; a first electrode penetrating the interlayer dielectric and connected to one end of the nanowire; and a second electrode penetrating the interlayer dielectric and connected to the other end of the nanowire.

The switching transistor comprises a nanowire; a first electrode connected to one end of the nanowire; a second electrode connected on the other end of the nanowire; a gate insulating layer covering the nanowire, the first electrode and the second electrode; and a gate electrode formed on the gate insulating layer corresponding to the nanowire.

The capacitor comprises a nanowire formed on the substrate; an insulating layer surrounding the nanowire; a first electrode surrounding the insulating layer; and a second electrode connected to the nanowire exposed through the insulating layer. The substrate has a recess formed on an area thereof corresponding to the insulator.

The capacitor comprises a nanowire; a first electrode connected to the nanowire; an insulating layer covering the nanowire; and a second electrode formed on the insulating layer corresponding to the nanowire.

The first electrode is electrically connected to the first power line, and the second electrode is electrically connected to the second power line. Here, a work function of the first electrode is larger than that of the second electrode.

The gate electrode is formed of transparent conductive oxide or opaque metal.

The nanowire is formed of mixture or compound of CaS:Eu, ZnS:Sm, ZnS:Mn, Y₂O₂S :Eu, Y₂O₂S:Eu,Bi, Gd₂O₃ :Eu, (Sr,Ca,Ba,Mg)P₂O₇:Eu,Mn, CaLa₂S₄:Ce, SrY₂S₄:Eu, (Ca,Sr)S:Eu, SrS:Eu, Y₂O₃:Eu, YVO₄:Eu,Bi, ZnS:Tb, ZnS:Ce,Cl, ZnS:Cu,Al, Gd₂O₂S:Tb, Gd₂O₃:Tb,Zn, Y₂O₃:Tb,Zn, SrGa₂S₄:Eu, Y₂SiO₅:Tb, Y₂Si₂O₇:Tb, Y₂O₂S:Tb, ZnO:Ag, ZnO:Cu,Ga, CdS:Mn, BaMgAl₁₀O₁₇:Eu,Mn, (Sr,Ca,Ba)(Al,Ga)2S₄:Eu, Ca₈Mg(SiO₄)4Cl₂:Eu,Mn, YBO₃:Ce,Tb, Ba₂SiO₄:Eu, (Ba,Sr)2SiO₄:Eu, Ba₂(Mg,Zn)Si₂O₇:Eu, (Ba,Sr)Al₂O₄:Eu, Sr₂Si₃O₈,2SrCl₂:Eu, SrS:Ce, ZnS:Tm, ZnS:Ag,Cl, ZnS:Te, Zn₂SiO₄:Mn, YSiO₅:Ce, (Sr,Mg,Ca)10(PO₄)6Cl₂:Eu, BaMgAl₁₀O₁₇:Eu, BaMg₂Al₁₆O₂₇:Eu, YAG(yttrium, alumium, garnet) or mixture or compound utilizing CaxSrx-1Al₂O₃:Eu+2 obtained by synthesizing CaAl₂O₃ and SrAl₂O₃ , or any one selected from the group consisting of ZnO, In₂O₃, SnO₂, SiGe, GaN, InP, InAs, Ge, GaP, GaAs, GaAs/P, InAs/P, ZnS, ZnSe, CdS, CdSe or mixture or compound thereof. A dopant which is any one selected from the group consisting of Ce, Tm, Ag, Cl, Te, Mn, Eu, Bi, Tb, Cu, Zn, Ga or mixture or compound thereof may be further added to the nanowire.

The nanowire of the switching transistor or the capacitor is formed of any one selected from the group consisting of ZnO, In₂O₃, SnO₂, SiGe, GaN, InP, InAs, Ge, GaP, GaAs, GaAs/P, InAs/P, ZnS, ZnSe, CdS, CdSe or mixture or compound thereof. A dopant which is any one selected from the group consisting of Ce, Tm, Ag, Cl, Te, Mn, Eu, Bi, Tb, Cu, Zn, Ga or mixture or compound thereof may be further added to the nanowire of the switching transistor or the capacitor.

The first electrode and the second electrode of the switching transistor have the same work function. Instead of the work functions which differ from each other, a light shielding member is formed on or below the switching transistor.

### Advantageous Effects

One embodiment of the present invention provides the light emitting display device employing a nanowire light emitting element in which a nanowire is formed between electrodes having different work functions to emit the certain colored light when a current is applied to the nanowire, and so the light emitting display device has a simple structure without employing a backlight and a color filter having a complicated structure and adopted in a conventional liquid crystal display device.

Also, another embodiment of the present invention provides the light emitting display device in which the light emitting element as well as the transistor and the capacitor are fabricated with a nanowire, and so there is no need to utilize a complicated process such as a vacuum deposition and a tool such as a fine metal mask for a fabricating process.

In addition, yet another embodiment of the present invention provides the light emitting display device employing the a nanowire light emitting transistor having a function of semiconductor as well as a light emitting function to enable a fabricating process to be simplified and a light-emitting region to be increased in comparison with a driving circuit section.

Furthermore, further another embodiment of the present invention provides the light emitting display device which is not sensitive to moisture or an atmosphere to enable a light emitting characteristic to be maintained by only thin protective layer.

### DESCRIPTION OF DRAWINGS

FIG. 1a is a plane view showing a light emitting display device according to one embodiment of the present invention, FIG. 1 b is a plane view showing RGB pixel of FIG. 1a and FIG. 1c is a cross-sectional view showing another RGB pixel;

FIG. 2 is a circuit diagram illustrating a light emitting display device having a nanowire according to one embodiment of the present invention;

FIG. 3a and FIG. 3b are plane views illustrating pixels of light emitting display devices having horizontal-type and vertical-type light emitting elements respectively, according to another embodiment of the present invention;

FIG. 4a and FIG. 4b are plane views illustrating horizontal-type light emitting elements according to yet another embodiment of the present invention;

FIG. 5a and FIG. 5b are a plane view and a cross-sectional view illustrating a horizontal-type light emitting element according to further another embodiment of the present invention;

FIG. 6a and FIG. 6b are a plane view and a cross-sectional view illustrating a vertical-type light emitting element according to yet another embodiment of the present invention;

FIG. 7a is a cross-sectional view illustrating a nanowire bottom gate transistor according to another embodiment of the present invention and FIG. 7b is a cross-sectional view illustrating a nanowire bottom gate transistor according to yet another embodiment of the present invention;

FIG. 8 is a cross-sectional view illustrating a nanowire top gate transistor according to another embodiment of the present invention;

FIG. 9 is a cross-sectional view illustrating a nanowire top gate transistor according to yet another embodiment of the present invention;

FIG. 10 is a cross-sectional view illustrating a nanowire capacitor according to another embodiment of the present invention;

FIG. 11 is a cross-sectional view illustrating a capacitor according to yet another embodiment of the present invention;

FIG. 12 is a circuit diagram showing a light emitting display device having a nanowire light emitting transistor according to one embodiment of the present invention;

FIG. 13a and FIG. 13b are a plane view and a cross-sectional view illustrating a bottom gate nanowire light emitting transistor according to yet another embodiment of the present invention, and FIG. 13c is a cross-sectional view illustrating a nanowire bottom gate transistor (switching transistor) according to yet another embodiment of the present invention;

FIG. 14 is a cross-sectional view illustrating a top gate nanowire light emitting transistor according to yet another embodiment of the present invention;

FIG. 15 is a cross-sectional view illustrating a top gate nanowire light emitting transistor according to further another embodiment of the present invention.

### MODES OF THE INVENTION

Hereinafter, exemplary embodiments of the present invention will be described in detail with reference to the accompanying drawings. The following exemplary embodiments are described in order to enable those of ordinary skill in the art to embody and practice the invention.

Here, the elements having the similar structure and performing the similar function are indicated by the same reference numerals throughout the specification. In addition, the expression of “a portion is electrically connected to another portion” includes not only a case where the portions are directly connected to each other, but also a case where the portions are connected to each other through another element disposed therebetween.

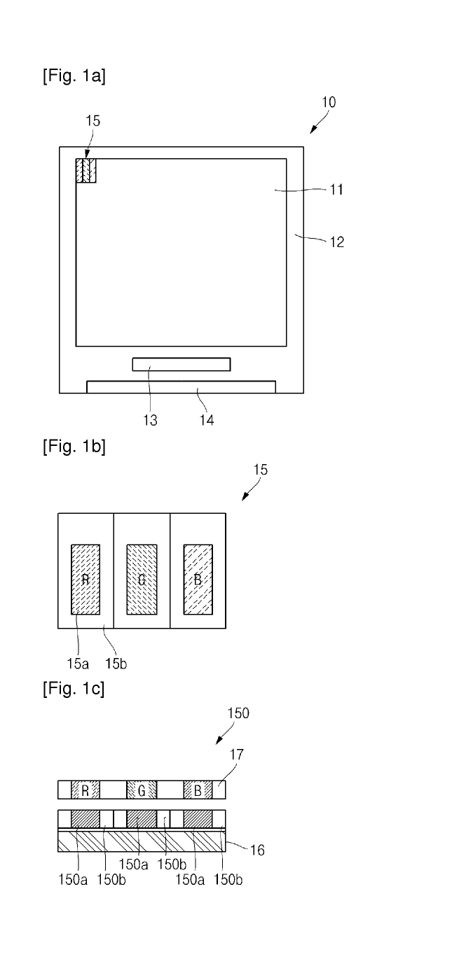

FIG. 1a is a plane view showing a light emitting display device according to one embodiment of the present invention, FIG. 1 b is a plane view showing a RGB pixel of FIG. 1a and FIG. 1c is a cross-sectional view showing another RGB pixel.

As shown in FIG. 1a, a light emitting display device 10 according to one embodiment of the present invention includes a display area 11, a non-display area 12, a driving driver 13 and an external connecting part 14. The number of N×M of pixels 15 are formed on the display area 11, and each pixel 15 consists of three (3) pixels, R, G, B pixels. Here, a color of the light emitted from the R, G and B pixels depends on material employing for forming a nanowire.

As shown in FIG. 1b, the pixel 15 according to one embodiment of the present invention may consist of a nanowire 15a, a circuit and a wire section 15b. The nanowire 15a is a part emitting one of the red-colored light, blue-colored light and green-colored light, the circuit and the wire section 15b are parts on which a transistor, a capacitor and a wire provided for driving and controlling the nanowire are formed.

As shown in FIG. 1c, a RGB pixel according to another embodiment of the present invention may include a nanowire 150a emitting a white-colored light, a circuit and a wire section 15b. In order to display each of the red, green and blue-colored light, at this time, a RGB color filter 17 may be arranged above or below the nanowire 150a emitting the white-colored light. Accordingly, although the nanowire 150a emits the which-colored light, since the RGB color filter 17 is arranged above or below the nanowire, the display device employing the above can display the colored light. Reference numeral 16 which is not illustrated indicates a substrate.

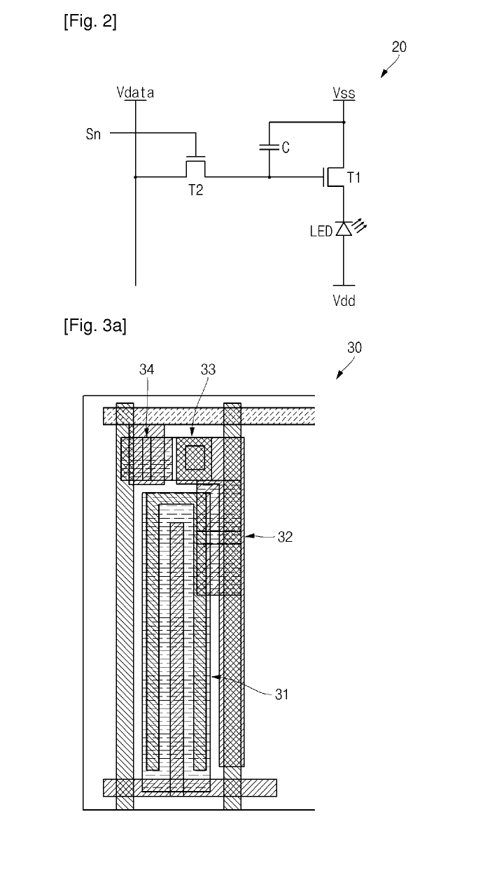

FIG. 2 is a circuit diagram illustrating a light emitting display device having a nanowire according to one embodiment of the present invention.

As shown in FIG. 2, a light emitting display device 20 having a nanowire according to one embodiment of the present invention includes a first power line Vdd, a light emitting element LED, a driving transistor T1, a second power line Vss, a capacitor C, a switching transistor T2, a data line Vdata and a scanning line Sn.

For example, the first power line Vdd supplies a voltage of approximately 5V. As compared with the conventional AMOLED, the light emitting element LED having the nanowire is operated by a low current, and so it is sufficient to supply a power of 5 volts to the first power line Vdd. However, the present invention is not limited to the above. In other words, the voltage which is lower or higher than the above voltage may be supplied to the light emitting element having the nanowire via the first power line Vdd.

The light emitting element LED having the nanowire includes a plurality of nanowires formed of inorganic luminescence material, a first electrode electrically connected to one end of the nanowire and a second electrode electrically to the other end of the nanowire. Here, the first electrode is electrically connected to the first power line Vdd. Thus, the first electrode can be an anode. The second electrode is electrically connected to the driving transistor T1. Accordingly, the second electrode can be a cathode. Various structures of the light emitting element LED having the nanowire and constructed as described above will be illustrated below.

The driving transistor T1 is electrically connected to the light emitting element LED. The driving transistor T1 includes a first electrode, a second electrode and a gate electrode. The first electrode (source or drain) of the driving transistor T1 is electrically connected to the second electrode of the light emitting element LED. The second electrode (drain or source drain) of the driving transistor T1 is electrically connected to the second power line Vss. The gate electrode of the driving transistor T1 is electrically connected to the capacitor C and the switching transistor T2. On the other hand, the above driving transistor T1 may also include the nanowire. Various structures of such driving transistor T1 will be illustrated below.

The second power line Vss supplies a voltage which is lower than a voltage supplied by the first power line Vdd. For example, the second power line Vss may supply a ground voltage. However, the present invention is not limited to the above. In other words, the voltage which is higher or lower than the ground voltage may be supplied to the light emitting element LED having the nanowire via the second power line Vss.

The capacitor C is electrically connected to the driving transistor T1, the switching transistor T2 and the second power line Vss. The capacitor C has a first electrode and a second electrode. The first electrode of the capacitor C is electrically connected to a gate electrode of the driving transistor T1 and the switching transistor T2. The second electrode of the capacitor C is electrically connected to the second power line Vss and the second electrode of the driving transistor T1. In the meantime, the above capacitor C may also include the nanowire. Various structures of the capacitor C will be illustrated below.

The switching transistor T2 is electrically connected to the driving transistor T1, the capacitor C, the data line Vdata and the scanning line Sn. The switching transistor T2 includes a first electrode, a second electrode and a gate electrode. The first electrode of the switching transistor T2 is electrically connected to the gate electrode of the driving transistor T1 and the first electrode of the capacitor C1. The second electrode of the switching transistor T2 is electrically connected to the data line Vdata. The gate electrode of the switching transistor T2 is electrically connected to the scanning line Sn. In the meantime, the above switching transistor T2 may also include the nanowire. Various structures of the switching transistor T2 will be illustrated below.

The data line Vdata supplies the data signal. The data supplied by the data line Vdata is stored in the capacitor C through the switching transistor T2.

The scanning line Sn supplies the scan signal. The switching transistor T2 is turned-on by the scan signal supplied through the scanning line Sn. In addition, when switching transistor T2 is turned-on as described above, the data supplied through the data line Vdata is stored in the capacitor C.

In the above, the light emitting display circuit 20 consisting of two transistors and one capacitor is illustrated as an example. However, it is natural that all the light emitting display circuits which have been known or will be known for improving a performance of the light emitting display device may be employed.

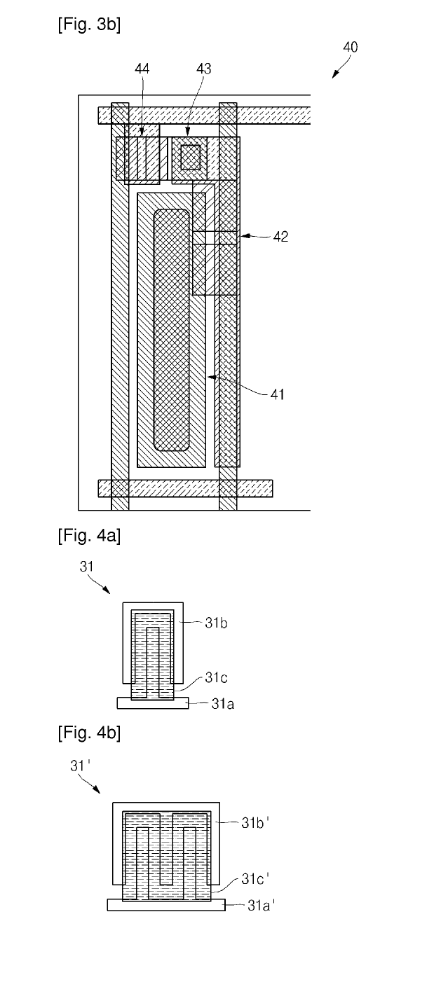

FIG. 3a and FIG. 3b are plane views illustrating pixels of light emitting display devices having horizontal-type and vertical-type light emitting elements respectively, according to another embodiment of the present invention;

As shown in FIG. 3a, the pixel 30 of the light emitting display device having a horizontal-type light emitting element includes a light emitting element 31 having a nanowire formed in the horizontal direction, a driving transistor 32 electrically connected to the light emitting element 31, a capacitor 33 and a switching transistor 34. Here, to increase the light extracting efficiency, the horizontal-type light emitting element 31 has the largest size or area, and the structure thereof will be illustrated below.

As shown in FIG. 3b, the pixel 40 of the light emitting display device having a vertical-type light emitting element includes a light emitting element 41 having a nanowire formed in the vertical direction, a driving transistor 42 electrically connected to the light emitting element 41, a capacitor 43 and a switching transistor 44. Here, to increase the light extracting efficiency, the vertical-type light emitting element 41 has the largest size or area, and the structure thereof will be illustrated below.

In the above, the pixel layout of the pixels 30, 40 consisting of two transistors and one capacitor is illustrated as an example. However, it is natural that the layouts of all the pixels which have been known or will be known for improving a performance of the pixel may be employed.

FIG. 4a and FIG. 4b are plane views illustrating horizontal-type light emitting elements according to yet another embodiment of the present invention.

As shown in FIG. 4a, a horizontal-type light emitting element 31 according to another embodiment of the present invention includes a first electrode 31a (or a second electrode) having a rough “⊥” shape; a rough “∩” shaped second electrode 31b (or a first electrode) spaced apart from the first electrode 31a and surrounding the first electrode 31a; and a plurality of nanowires 31c formed between the first electrode 31a and the second electrode 31b and electrically connected to the first electrode 31a and the second electrode 31b.

As shown in FIG. 4b, a horizontal-type light emitting element 31 according to yet another embodiment of the present invention includes a first electrode 31a′ (or a second electrode) having a rough “ [symbol] ” shape; a rough “∩” shaped second electrode 31b′ (or a first electrode) spaced apart from the first electrode 31a′ and surrounding the first electrode 31a1; and a plurality of nanowires 31c′ formed between the first electrode 31a′ and the second electrode 31b′.

In the horizontal-type light emitting elements 31, 31′ according to another embodiment of the present invention, due to the above structures, as many nanowires as possible are formed and arranged between the first electrode and second electrode and electrically connected the first electrode and second electrode, and so the light extracting efficiency is maximized.

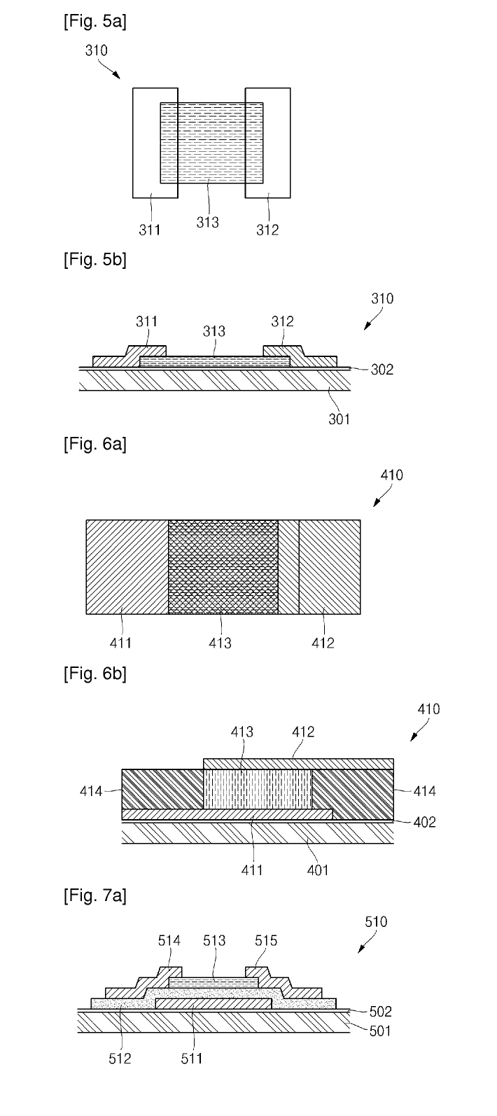

FIG. 5a and FIG. 5b are a plane view and a cross-sectional view illustrating horizontal-type light emitting elements according to further another embodiment of the present invention;

As shown in FIG. 5a and FIG. 5b, a light emitting element 310 according to further another embodiment of the present invention includes a plurality of nanowires 313 formed on a substrate 301; a first electrode 311 covering one end portion of the nanowire 313 and inner circumference surface and outer circumference surface of one end portion; and a second electrode 312 covering the other end portion of the nanowire 313 and inner circumference surface and outer circumference surface of the other end portion. Here, the first electrode 311 may be electrically connected to a first power line, and the second electrode 312 may be electrically connected to a second power line. In addition, the first electrode 311 and the second electrode 312 may be flush with each other and spaced apart from each other in the horizontal direction.

The substrate 301 may be one selected from a ceramic substrate, a silicon wafer substrate, a glass substrate, a polymer substrate and an equivalent thereof. In particular, in a case where the light emitting element having the nanowire is provided in a transparent light emitting display device, the substrate may be formed of glass or transparent plastic. The glass substrate may be formed of silicon oxide. In addition, the polymer substrate may be formed of polymer material such as polyethyleneterephthalate (PET), polyethylenenaphthalate (PEN), polyimide. Reference numeral 302 in the drawing, which is not illustrated, indicates a buffer layer.

The first electrode 311 is formed in the shape of a thin layer and may be utilized as an anode. In addition, the first electrode 311 simultaneously covers one end portion of the nanowire 313 and an internal and external circumference surfaces of one end portion of the nanowire so that the first electrode is electrically connected to the nanowire 313. The first electrode 311 may be formed of one metal selected from aluminum (Al), tin (Sn), tungsten (W), aurum (Au), chrome (Cr), molybdenum (Mo), palladium (Pd), platinum (Pt), nickel (Ni), titanium (Ti) and equivalents thereof. In addition, the first electrode 311 may be formed of one transparent conductive oxide selected from indium tin oxide (ITO), indium zinc oxide (IZO), zinc oxide, tin oxide (SnO₂), indium oxide (In₂O₃) and equivalent thereof.

A plurality of nanowires 313 are provided to form a thin layer having a certain thickness. It goes without saying that such nanowires 313 are electrically connected to the first electrode 311 and the second electrode 312. In addition, the nanowire 313 may be arranged such that the lengthwise direction of the nanowire is paralleled with or perpendicular to the lengthwise direction of the first electrode 311 (or the second electrode). In other words, the nanowire 313 may be formed such that the nanowire is traversed from one end to the other end of the first electrode 311 (or the second electrode) in the lengthwise direction of the first electrode 311 (or the second electrode) or directed outwardly from a plane surface of the first electrode 311 (or the second electrode) in the outward direction.

The nanowire 313 is formed in the shape of wire having a length larger than a diameter. The diameter of the nanowire is approximately 1 nm to 300 nm, and the length is approximately 2 nm to 500 μm. The uniformity of thickness of the thin layer of the nanowire 313 is inversely proportional to the diameter of the nanowire 313. On the other hand, if the diameter of the nanowire 313 is larger than approximately 300 nm, a thickness of the thin layer of the nanowire 313 is partially increased so that a flatness of thin layer of the nanowire 313 is deteriorated.

In the meantime, the nanowire 311 is formed of inorganic luminescence material. According to the color, various phosphors may be employed as inorganic luminescence material.

For example, phosphors such as mixture or compound of CaS:Eu, ZnS:Sm, ZnS:Mn, Y₂O₂S:Eu, Y₂O₂S :Eu,Bi, Gd₂O₃:Eu, (Sr,Ca,Ba,Mg)P₂O₇:Eu,Mn, CaLa₂S₄:Ce; SrY₂S₄:Eu, (Ca,Sr)S:Eu, SrS:Eu, Y₃O₃:Eu, YVO₄:Eu,Bi, which are red phosphors, may be utilized as inorganic luminescence material.

In addition, phosphors such as each of ZnS:Tb, ZnS:Ce,Cl, ZnS:Cu,Al, Gd₂O₂S:Tb, Gd₂O₃:Tb,Zn, Y₂O₃:Tb,Zn, SrGa₂S₄:Eu, Y₂SiO₅:Tb, Y₂Si₂O₇:Tb, Y₂O₂S:Tb, ZnO:Ag, ZnO:Cu,Ga, CdS:Mn, BaMgAl₁₀O₁₇:Eu,Mn, (Sr,Ca,Ba)(Al,Ga)2S₄:Eu, Ca₈Mg(SiO₄)4Cl₂:Eu,Mn, YBO₂₃:Ce,Tb, Ba₂SiO₄:Eu, (Ba,Sr)2SiO₄:Eu, Ba₂(Mg,Zn)Si₂O₇:Eu, (Ba,Sr)Al₂O₄:Eu, Sr₂Si₃O₈.2SrCl₂:Eu, which are green phosphors, or mixture or compound thereof may be utilized as inorganic luminescence material.

Also, phosphors such as each of SrS:Ce, ZnS:Tm, ZnS:Ag,Cl, ZnS:Te, Zn₂SiO₄:Mn, YSiO₅:Ce, (Sr,Mg,Ca)10(PO₄)6Cl₂:Eu, BaMgAl₁₀O₁₇:Eu, BaMg₂Al₁₆O₂₇:Eu, which are blue phosphors, or mixture or compound thereof may be utilized as inorganic luminescence material.

In addition, white phosphor such as YAG (yttrium, aluminum, garnet) may be utilized as inorganic luminescence material. Also, as inorganic luminescence material, mixture or compound utilizing CaxSrx-1Al₂O₃:Eu+2 obtained by synthesizing CaAl₂O₃ and SrAl₂O₃ may be employed. In addition, white-colored light may be obtained by mixing ZnO+SnO with the above inorganic luminescence material

Here, the inorganic luminescence material includes a host forming a substance and a dopant acting as a light emitting center in the substance.

In general, the substance such as Si, Ge, Sn, Se, Te, B, C (including diamond) P, B—C, B—P(BP₆), B—Si, Si—C, Si—Ge, Si—Sn and Ge—Sn, SiC, BN/BP/BAs, AlN/AlP/AlAs/AlSb, GaN/GaP/GaAs/GaSb, InN/InP/InAs/InSb, BN/BP/BAs, AlN/AlP/AlAs/AlSb, GaN/GaP/GaAs/GaSb, InN/InP/InAs/InSb, ZnO/ZnS/ZnSe/ZnTe, CdS/CdSe/CdTe, HgS/HgSe/HgTe, BeS/BeSe/BeTe/MgS/MgSe, GeS, GeSe, GeTe, SnS, SnSe, SnTe, PbO, PbS, PbSe, PbTe, CuF, CuCl, CuBr, CuI, AgF, AgCl, AgBr, AgI, BeSiN₂, CaCN₂, ZnGeP₂, CdSnAs₂, ZnSnSb₂, CuGeP₃, CuSi₂P₃, Si₃N4, Ge₃N4, Al₂O₃, Al₂CO may be employed for forming the semiconductor nanowire.

Basically, in particular, the nanowire formed of material such as each of ZnO, In₂O₃, SnO₂, SiGe, GaN, InP, InAs, Ge, GaP, GaAs, GaAs/P, InAs/P, ZnS, ZnSe, CdS, CdSe, or mixture or compound thereof has a function of semiconductor and has a light emitting function by addition of separate dopant. Of course, by adjusting a composition of the dopant, it is possible to adjust appropriately a color of the emitted light. In addition, each of Ce, Tm, Ag, Cl, Te, Mn, Eu, Bi, Tb, Cu, Zn, Ga, or mixture or compound thereof may be employed as dopant, however, the present invention is not limited to the above material.

In the meantime, a planarizing layer (not shown) may be further formed in or on a gap between the nanowires 313. According to the electrical characteristics of the nanowire 313, a dielectric layer or an electric conductive layer may be formed as the planarizing layer. If the nanowire 313 has an electric conductivity, since a charge is not accumulated on a surface of the nanowire, a dielectric layer or an insulating layer may be formed as the planarizing layer. In addition, if the nanowire 313 does not have an electric conductivity, since a charge is accumulated on a surface of the nanowire when a low voltage is excited, an electric conductive layer may be formed as the planarizing layer for preventing an accumulation of charge. The planarizing layer fills a gap between the nanowires 313 to enable the overall nanowires to be planarized. The planarizing layer may be formed of dielectric material, high molecular resin or oxide.

The second electrode 312 is also formed in the shape of a thin layer having a certain thickness and has the opposite polarity to that of the first electrode 311. In the other words, if the first electrode 311 is an anode, the second electrode 312 may be used as a cathode. The second electrode 312 is electrically connected to the nanowire 313. That is, the second electrode 312 covers simultaneously the other end of the nanowire 313 and inner and outer circumference surfaces of the other end so that the second electrode 312 is electrically connected to the nanowire 313. In addition, the second electrode 312 may be a metal layer formed of one selected from aluminum (Al), tin (Sn), tungsten (W), aurum (Au), chrome (Cr), molybdenum (Mo), palladium (Pd), platinum (Pt), nickel (Ni), titanium (Ti) and equivalents thereof. Also, the second electrode 312 may be formed of one transparent conductive oxide selected from indium tin oxide (ITO), indium zinc oxide (IZO), zinc oxide, tin oxide (SnO₂), indium oxide (In₂O₃) and equivalent thereof.

Meanwhile, if the work function of the first electrode 311 does not differ from that of the second electrode 312, it is difficult to emit the light from the nanowire 313. Accordingly, if the first electrode 311 is employed as the anode, the first electrode 311 is preferably formed of one selected from indium tin oxide (ITO), indium zinc oxide (IZO), zinc oxide, tin oxide (SnO₂), indium oxide (In₂O₃) having a relatively high work function, and equivalent thereof. The work function of the above materials is approximately 4.9 eV which is a relatively high work function.

In addition, if the second electrode 312 is employed as the cathode, the second electrode 312 is preferably formed of one selected from aluminum having a relatively low work function, and equivalent thereof. The work function of the above materials is approximately 4.1 eV which is a relatively low work function.

Moreover, in case where the first electrode 311 formed of indium tin oxide (ITO), indium zinc oxide (IZO), zinc oxide, tin oxide (SnO₂), indium oxide (In₂O₃) is used as the cathode, in order to maintain a difference of the work function between the first electrode and the second electrode 312, magnesium or aluminum may be deposited in advance before forming the first electrode 311.

In addition, the first electrode 311 is flush with the second electrode 312 and the first electrode 311 and the second electrode 312 are spaced apart from each other in the horizontal direction so that the horizontal-type light emitting element 310 is realized. Furthermore, in case of the above horizontal-type light emitting element 310, a bidirectional light emitting structure by which the light is emitted in the upward direction and the downward direction can be obtained, and by forming additionally an opaque reflective layer on or below the light emitting element, the light emitting direction can be adjusted to emit the light in only one direction.

FIG. 6a and FIG. 6b are a plane view and a cross-sectional view illustrating a vertical-type light emitting element according to yet another embodiment of the present invention.

As shown in FIG. 6a and FIG. 6b, a vertical-type light emitting element 410 according to yet another embodiment of the present invention includes a nanowire 413, a first electrode 411 formed below the nanowire 413 and a second electrode 412 formed above the nanowire 413.

As illustrated above, the nanowire 413, the first electrode 411 and the second electrode 412 are formed of the same material. In addition, the work function of the first electrode 411 differs from that of the second above the nanowire 413 to generate a light emitting phenomenon on the nanowire 413.

In addition, the first electrode 411 is not flush with the second electrode 412 and the first electrode and the second electrode are spaced apart from each other in the vertical direction so that the vertical-type light emitting element 310 is provided. In case of the above vertical-type light emitting element 410, since locations at which the first electrode 411 and the second electrode 412 are formed respectively, can be interchanged with each other, according to the direction in which the light is emitted, a transparent anode electrode (for example, formed of ITO/IZO and the like) and an opaque cathode electrode (for example, formed of aluminum) can be properly arranged to determine the direction in which the light is emitted. The reference numeral 414 in the drawing, which is not illustrated, indicates an insulating layer.

Yet another embodiment of the present invention illustrated below illustrates that the light emitting element as well as the driving transistor, the switching transistor and the capacitor consists of the nanowire. Thus, the light emitting display device according to the present invention can utilize the common nanowire to realize a plurality of elements (the light emitting element, the driving transistor, the switching transistor and the capacitor), and so one skilled in the art can understand that this structure simplifies significantly a fabricating process.

Hereinafter, the structures of the driving transistor, the switching transistor and the capacitor formed by the nanowire are illustrated. Here, since the driving transistor and the switching transistor have the same structure, it should be understood that bottom gate transistor or a top gate transistor is regarded as the driving transistor and the switching transistor. Furthermore, a nanowire which is the same kind of the nanowire having the above-mentioned light emitting characteristic is employed. In other words, the nanowire is formed of material such as each of ZnO, In₂O₃, SnO₂, SiGe, GaN, InP, InAs, Ge, GaP, GaAs, GaAs/P, InAs/P, ZnS, ZnSe, CdS, CdSe or mixture or compound thereof. Undoubtedly, a dopant is added to the above material, the dopant may be one of Ce, Tm, Ag, Cl, Te, Mn, Eu, Bi, Tb, Cu,

Zn, Ga or mixture or compound thereof.

In the meantime, since there is no difference between a first electrode and a second electrode of the transistor described below, a light emitting phenomenon basically does not occur. Accordingly, an unnecessary light emitting phenomenon is not generated during an operation of the transistor.

However, even though the first electrode and the second electrode having the work functions which differ from each other are employed, by forming a light shielding member on or below the transistor, it is possible to prevent the light emitted from the transistor from being radiated to an outside of the display device.

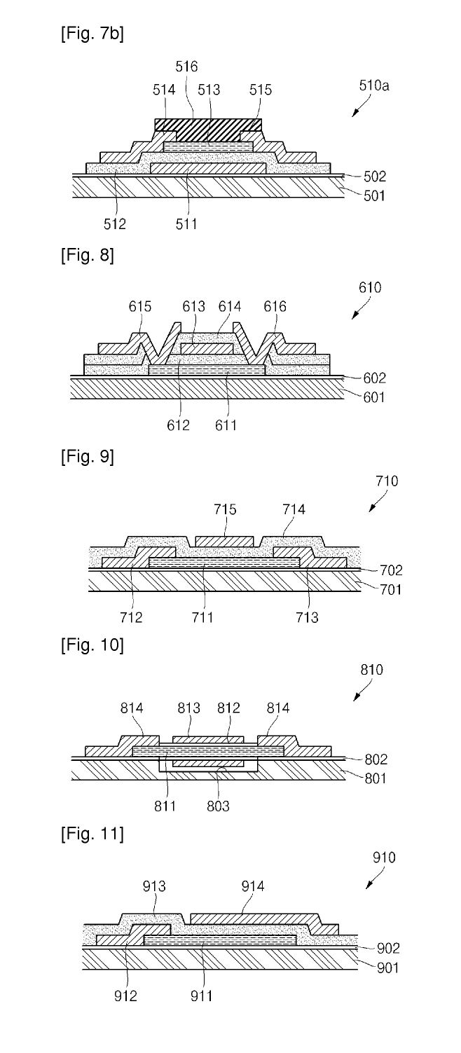

FIG. 7a is a cross-sectional view illustrating a nanowire bottom gate transistor according to another embodiment of the present invention and FIG. 7b is a cross-sectional view illustrating a nanowire bottom gate transistor according to yet another embodiment of the present invention;

As shown in FIG. 7a, a nanowire bottom gate transistor 510 according to another embodiment of the present invention includes a gate electrode 511 formed on a buffer layer 502 of a substrate 501; a gate insulating layer 512 covering the gate electrode 511; a nanowire 512 formed on the gate insulating layer 512 corresponding to the gate electrode 511; a first electrode 514 connected to one end of the nanowire 513; and a second electrode 515 connected to the other end of the nanowire 513.

Here, the first electrode 514 and the second electrode 515 may be a metal layer formed of one metal selected from aluminum (Al), tin (Sn), tungsten (W), aurum (Au), chrome (Cr), molybdenum (Mo), palladium (Pd), platinum (Pt), nickel (Ni), titanium (Ti) and equivalents thereof. In addition, the second electrode 514 and the second electrode 515 may be formed of one transparent conductive oxide selected from indium tin oxide (ITO), indium zinc oxide (IZO), zinc oxide, tin oxide (SnO₂), indium oxide (In₂O₃) and equivalent thereof. In addition, since the nanowire 513 disposed between and electrically connected to the first electrode 514 and second electrode 515 should not emit the light, it is preferable that the first electrode 514 and the second electrode 515 are formed of the materials having the same work function. For example, if the first electrode 514 is formed of aluminum, the second electrode 515 is formed of aluminum.

As shown in FIG. 7b, a light-shielding member 516 may be further formed on or below a bottom gate transistor 510a according to yet another embodiment of the present invention. As described above, in a case where the first electrode 514 and the second electrode 515 having the work functions which differ from each other are utilized, the nanowire 513 can emit the light. However, it is possible to prevent the light emitted from the nanowire 513 from being radiated to an outside of the display device by the light-shielding member 516. Basically, the above light-shielding member may be provided in a driving transistor and a switching transistor described below.

FIG. 8 is a cross-sectional view illustrating a top gate transistor according to another embodiment of the present invention.

A top gate transistor 610 according to another embodiment of the present invention includes a nanowire 611 formed on a buffer layer 602 of a substrate 601; a gate insulating layer 612 covering the nanowire 611; a gate electrode 613 formed on the gate insulating layer 612 corresponding to the nanowire 611; an interlayer dielectric 614 covering the gate electrode 613 and the gate insulating layer 612 corresponding to a periphery the gate electrode; a first electrode 615 penetrating the interlayer dielectric 614 and connected to one end of the nanowire 611 via the penetrating portion thereof; and a second electrode 616 penetrating the interlayer dielectric 614 and connected to the other end of the nanowire 611 via the penetrating portion thereof

Here, the first electrode 615 and the second electrode 616 may be formed of the material which is the same material as described above. In addition, so as not to allow the nanowire 611 to emit the light, the electrode 615 and the second electrode 616 are formed of the materials, respectively, having the same work function.

FIG. 9 is a cross-sectional view illustrating a top gate transistor according to yet another embodiment of the present invention.

As shown in FIG. 9, a top gate transistor 710 according to yet another embodiment of the present invention includes a nanowire 711 formed on a buffer layer 702 of a substrate 701; a first electrode 712 connected to one end of the nanowire 711; a second electrode 712 connected to the other end of the nanowire 711; a gate insulating layer 714 covering the nanowire 711, the first electrode 712 and the second electrode 712; and a gate electrode 715 formed on the gate insulating layer 714 corresponding to the nanowire 711.

Here, the first electrode 712 and the second electrode 713 may be formed of the material which is the same material as described above. In addition, so as not to allow the nanowire 711 to emit the light, the first electrode 712 and the second electrode 713 are formed of the materials, respectively, having the same work function.

FIG. 10 is a cross-sectional view illustrating a capacitor according to another embodiment of the present invention.

As shown in FIG. 10, a capacitor 810 according to another embodiment of the present invention includes a nanowire 811 formed on a substrate 801 having a recess 803 formed thereon and having a certain depth; an insulating layer 812 surrounding the nanowire 811; a first electrode 813 surrounding the insulating layer 812; and a second electrode 814 connected to the nanowire 811 exposed through the insulating layer 812. Here, since the nanowire 811 is electrically connected to the second electrode 814, the nanowire 811 opposed to the first electrode 811 forms one capacitor.

Here, the first electrode 813 and the second electrode 814 may be formed of the material which is the same material as described above. In addition, so as not to allow the nanowire 811 to emit the light, the first electrode 813 and the second electrode 8143 are formed of the materials, respectively, having the same work function. Reference numeral 802 which is not illustrated indicates a buffer layer. There is no doubt that, basically, since the capacitor is not a current element, even though there is a work function difference between of the first electrode 813 and the second electrode 814, the light is not emitted. In other words, the first electrode 813 and the second electrode 814 having the work functions which differs from each other may be employed in the capacitor.

FIG. 11 is a cross-sectional view illustrating a capacitor according to yet another embodiment of the present invention.

As shown in FIG. 11, a capacitor 910 according to yet another embodiment of the present invention includes a nanowire 911 formed on a substrate 901; a first electrode 912 electrically connected to the nanowire 911; an insulating layer 913 covering the nanowire 911; and a second electrode 914 formed on the insulating layer 913 corresponding to the nanowire 911. Here, since the nanowire 911 is also electrically connected to the first electrode 912, the nanowire 911 opposed to the second electrode 914 forms one capacitor.

The first electrode 912 and the second electrode 914 may be formed of the material which is the same material as described above. In addition, so as not to allow the nanowire 911 to emit the light, the first electrode 912 and the second electrode 914 are formed of the materials, respectively, having the same work function.

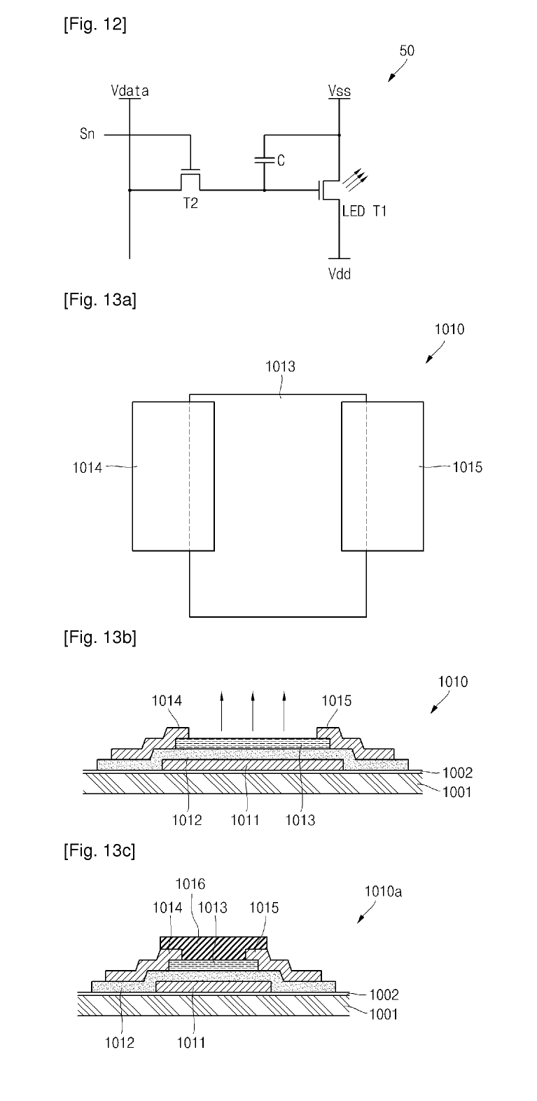

FIG. 12 is a circuit diagram showing a light emitting display device having a nanowire light emitting transistor according to yet another embodiment of the present invention.

As shown in FIG. 12, a light emitting display device 50 according to yet another embodiment of the present invention includes a first power line Vdd, a nanowire light emitting transistor LED T1, a second power line Vss, a capacitor C, a switching transistor T2, a data line Vdata and a scanning line Sn.

For example, the first power line Vdd supplies the voltage of approximately 5V. Here, in comparison with a conventional AMOLED, since the nanowire light emitting transistor LED T1 is operated with a low current, the voltage of 5 V is sufficient for a power to be supplied to the first power line Vdd. However, the present invention is not limited thereto. In other words, a voltage which is lower or higher than the above voltage may be supplied to the nanowire light emitting transistor LED T1 through the first power line Vdd.

The nanowire light emitting transistor LED T1 is electrically connected to the first power line Vdd. The nanowire light emitting transistor LED T1 includes a first electrode, a second electrode and a gate electrode. The first electrode (source or drain) of the nanowire light emitting transistor LED T1 is electrically connected to the first power line Vdd. The second electrode (drain or source) of the nanowire light emitting transistor LED T1 is electrically connected to the second power line Vss. The gate electrode of the nanowire light emitting transistor LED T1 is electrically connected to the capacitor C and the switching transistor T2. In the meantime, the nanowire light emitting transistor LED T1 includes the nanowire having a semiconductor function and a light emitting function. In other words, the nanowire light emitting transistor LED T1 is turned-on under the condition, for example, Vgs>Vth. At this time, the prescribed colored-light is emitted. The detail structure of the above nanowire light emitting transistor LED T1 will be illustrated below.

The second power line Vss supplies a voltage lower than a voltage supplied from the first power line Vdd. For example, the second power line Vss can supply a ground voltage. However, the present invention is not limited thereto. In other words, a voltage which is higher or lower than the ground voltage can be supplied to the nanowire light emitting transistor LED T1 through the second power line Vss.

The capacitor C is electrically connected to the nanowire light emitting transistor LED T1, the switching transistor T2 and the second power line Vss. The capacitor C has a first electrode and a second electrode. The first electrode of the capacitor C is electrically connected to a gate electrode of the nanowire light emitting transistor LED T1 and the switching transistor T2. The second electrode of the capacitor C is electrically connected to the second power line Vss and a second electrode of the nanowire light emitting transistor LED T1. The above capacitor C may include the nanowire. Various structures of such capacitor C will be illustrated again below.

The switching transistor T2 is electrically connected to the nanowire light emitting transistor LED T1, the capacitor C, the data line Vdata and the scanning line Sn. The switching transistor T2 includes a first electrode, a second electrode and a gate electrode. The first electrode of the switching transistor T2 is electrically connected to the gate electrode of the nanowire light emitting transistor LED T1 and the first electrode of the capacitor C. The second electrode of the switching transistor T2 is electrically connected to the data line Vdata. The gate electrode of the switching transistor T2 is electrically connected to the scanning line Sn. In the meantime, the above switching transistor T2 may also include the nanowire. Such switching transistor T2 is substantially the same as the nanowire light emitting transistor LED T1. In the switching transistor T2, the work function of the first electrode is the same as that of the second electrode. In the nanowire light emitting transistor LED T1, however, the work function of the first electrode differs from that of the second electrode

The data line Vdata supplies the data signal. The data supplied by the data line Vdata is stored in the capacitor C through the switching transistor T2.

The scanning line Sn supplies the scan signal. The switching transistor T2 is turned-on by the scan signal supplied through the scanning line Sn. In addition, when switching transistor T2 is turned-on as described above, the data supplied through the data line Vdata is stored in the capacitor C.

In the above, even though the light emitting display circuit 20 consisting of two transistors and one capacitor (2TR 1CAP) is illustrated by way of example, it is natural that all the light emitting display circuits which have been known or will be known for improving a performance of the light emitting display device may be employed.

FIG. 13a and FIG. 13b are a plane view and a cross-sectional view illustrating a bottom gate nanowire light emitting transistor according to yet another embodiment of the present invention, and FIG. 13c is a cross-sectional view illustrating a nanowire bottom gate transistor (switching transistor) according to yet another embodiment of the present invention;

As shown in FIG. 13a and FIG. 13b, a bottom gate nanowire light emitting transistor 1010 according to yet another embodiment of the present invention includes a gate electrode 1011 formed on a buffer layer 1002 of a substrate 1001; a gate insulating layer 1012 covering the gate electrode 1011; a nanowire 1013 formed on the gate insulating layer 1012 corresponding to the gate electrode 1011; a first electrode 1014 connected to one end of the nanowire 1013; and a second electrode 1015 connected to the other end of the nanowire 1013.

The substrate 1001 may be one selected from a ceramic substrate, a silicon wafer substrate, a glass substrate, a polymer substrate and equivalents thereof. In particular, in a case where the substrate is employed in a bidirectional light emitting display device, the substrate may be formed of glass or transparent plastic. The glass substrate may be formed of silicon oxide. In addition, the polymer substrate may be formed of polymer material such as polyethyleneterephthalate (PET), polyethylenenaphthalate (PEN), polyimide.

The gate electrode 1011 is formed on the buffer layer substrate 1001 of the substrate 1001. In a case where the light emitted from the display device is radiated upward, this gate electrode 1011 may be formed of an opaque reflective metal. For example, the gate electrode 1011 may be formed of one opaque reflective metal selected from aluminum (Al), tin (Sn), tungsten (W), aurum (Au), chrome (Cr), molybdenum (Mo), palladium (Pd), platinum (Pt), nickel (Ni), titanium (Ti) and equivalents thereof. In addition, in a case where the light emitted from the display device is radiated in the downward direction or in the both directions, this gate electrode 1011 may be formed of a transparent conductive oxide. For example, the gate second electrode 1011 may be formed of one transparent conductive oxide selected from indium tin oxide (ITO), indium zinc oxide (IZO), zinc oxide, tin oxide (SnO₂), indium oxide (In₂O₃) and equivalents thereof.

The gate insulating layer 1012 covers the gate electrode 1012 and a buffer layer 1012 corresponding to a periphery of the gate electrode. The gate insulating layer 1012 may be one selected from a conventional oxide layer, a nitride layer and equivalent thereof.

The nanowire 1013 is formed on the gate insulating layer 1012 corresponding to the gate electrode 1011. Such nanowire 1013 has a light emitting function as well as a function of semiconductor.

A plurality of nanowires 1013 are provided to form a thin layer having a certain thickness on the gate insulating layer 1012. Undoubtedly, the nanowire 1013 is electrically connected to the first electrode 1014 and the second electrode 1015 described below. In addition, the nanowire 1313 may be arranged such that the lengthwise direction of the nanowire is paralleled with or perpendicular to the lengthwise direction of the first electrode 1014 (or the second electrode). In other words, the nanowire 1013 may be formed such that the nanowire is traversed from one end to the other end of the first electrode 1014 (or the second electrode) in the lengthwise direction of the first electrode 1014 (or the second electrode) or directed outwardly from a plane surface of the first electrode 1014 (or the second electrode) in the outward direction.

The nanowire 1013 is formed in the shape of wire having a length larger than a diameter. The diameter of the nanowire is approximately 1 nm to 300 nm, and the length is approximately 2 nm to 500 μm. The uniformity of thickness of the thin layer of the nanowire 313 is inversely proportional to the diameter of the nanowire 1013. On the other hand, if the diameter of the nanowire 1013 is larger than approximately 300 nm, a thickness of the thin layer of the nanowire 1013 is partially increased so that a flatness of the thin layer of the nanowire 1013 is deteriorated.

In the meantime, the nanowire 1311 is formed of inorganic luminescence material. According to the color, various phosphors may be employed as inorganic luminescence material.

For example, phosphors such as each of CaS:Eu, ZnS:Sm, ZnS:Mn, Y₂O₂S:Eu, Y₂O₂S:Eu,Bi, Gd₂O₃:Eu, (Sr,Ca,Ba,Mg)P₂O₇:Eu,Mn, CaLa₂S₄:Ce; SrY₂S₄:Eu, (Ca,Sr)S:Eu, SrS:Eu, Y₃O₃:Eu, YVO₄:Eu,Bi, which are red phosphors, or mixture or compound thereof may be utilized as inorganic luminescence material.

In addition, phosphors such as each of ZnS:Tb (host;dopant), ZnS:Ce,Cl, ZnS:Cu,Al, Gd₂O₂S:Tb, Gd₂O₃:Tb,Zn, Y₂O₃:Tb,Zn, SrGa₂S₄:Eu, Y₂SiO₅:Tb, Y₂Si₂O₇:Tb, Y₂O₂S:Tb, ZnO:Ag, ZnO:Cu,Ga, CdS:Mn, BaMgAl₁₀O₁₇:Eu,Mn, (Sr,Ca,Ba)(Al,Ga)2S₄:Eu, Ca₈Mg(SiO₄)4Cl₂:Eu,Mn, YBO₃:Ce,Tb, Ba₂SiO₄:Eu, (Ba,Sr)2SiO₄:Eu, Ba₂ (Mg,Zn)Si₂O₇:Eu, (Ba,Sr)Al₂O₄:Eu, Sr₂Si₃O₈.2SrCl₂:Eu, which are green phosphors, or mixture or compound thereof may be utilized as inorganic luminescence material.

Also, phosphors such as each of SrS:Ce, ZnS:Tm, ZnS:Ag,Cl, ZnS:Te, Zn₂SiO₄:Mn, YSiO₅:Ce, (Sr,Mg,Ca)10(PO₄)6Cl₂:Eu, BaMgAl₁₀O₁₇:Eu, BaMg₂Al₁₆O₂₇:Eu, which are blue phosphors, or mixture or compound thereof may be utilized as inorganic luminescence material.

In addition, white phosphor such as YAG (yttrium, aluminum, garnet) may be utilized as inorganic luminescence material. Also, as inorganic luminescence material, mixture or compound utilizing CaxSrx-1Al₂O₃:Eu+2 obtained by synthesizing CaAl₂O₃ and SrAl₂O₃ may be employed. In addition, white-colored light may be obtained by mixing ZnO+SnO with the above inorganic luminescence material

In other words, the inorganic luminescence material includes a host forming a substance and a dopant acting as a light emitting center in the substance. In addition, such inorganic luminescence material is formed on a semiconductor action layer and a semiconductor channel region in the transistor.

In general, the substance such as Si, Ge, Sn, Se, Te, B, C (including diamond) P, B—C, B—P(BP₆), B—Si, Si—C, Si—Ge, Si—Sn and Ge—Sn, SiC, BN/BP/BAs, AlN/AlP/AlPAs/AlSb, GaN/GaP/GaAs/GaSb, InN/InP/InAs/InSb, BN/BP/BAs, AlN/AlP/AlPAs/AlSb, GaN/GaP/GaAs/GaSb, InN/InP/InAs/InSb, ZnO/ZnS/ZnSe/ZnTe, CdS/CdSe/CdTe, HgS/HgSe/HgTe, BeS/BeSe/BeTe/MgS/MgSe, GeS, GeSe, GeTe, SnS, SnSe, SnTe, PbO, PbS, PbSe, PbTe, CuF, CuCl, CuBr, CuI, AgF, AgCl, AgBr, AgI, BeSiN₂, CaCN₂, ZnGeP₂, CdSnAs₂, ZnSnSb₂, CuGeP₃, CuSi₂P₃, Si₃N4, Ge₃N4, Al₂O₃, Al₂CO may be employed for forming the semiconductor nanowire.

Basically, in particular, the nanowire formed of material such as each of ZnO, In₂O₃, SnO₂, SiGe, GaN, InP, InAs, Ge, GaP, GaAs, GaAs/P, InAs/P, ZnS, ZnSe, CdS, CdSe, or mixture or compound thereof has a function of semiconductor and has a light emitting function by addition of separate dopant. Of course, by adjusting a composition of the dopant, it is possible to adjust appropriately a color of the emitted light. In addition, each of Ce, Tm, Ag, Cl, Te, Mn, Eu, Bi, Tb, Cu, Zn, Ga, or mixture or compound thereof may be employed as dopant, however, the present invention is not limited to the above material.

In the meantime, a planarizing layer (not shown) may be further formed in or on a gap between the nanowires 1013. According to the electrical characteristics of the nanowire 1313, a dielectric layer or an electric conductive layer may be formed as the planarizing layer. If the nanowire 1013 has an electric conductivity, since a charge is not accumulated on a surface of the nanowire, a dielectric layer or an insulating layer may be formed as the planarizing layer. In addition, if the nanowire 1013 does not have an electric conductivity, since a charge is accumulated on a surface of the nanowire when a low voltage is excited, an electric conductive layer may be formed as the planarizing layer for preventing an accumulation of charge. The planarizing layer fills a gap between the nanowires 1013 to enable the overall nanowires to be planarized. The planarizing layer may be formed of dielectric material, high molecular resin or oxide.

The first electrode 1014 is formed in the shape of a thin layer and may be employed as a source electrode (or a drain electrode). Also, the first electrode 1014 covers simultaneously one end of the nanowire 1013 and inner and outer circumference surfaces of one end so that the first electrode is electrically connected to the nanowire 1013. The first electrode 1014 may be formed of one metal selected from aluminum (Al), tin (Sn), tungsten (W), aurum (Au), chrome (Cr), molybdenum (Mo), palladium (Pd), platinum (Pt), nickel (Ni), titanium (Ti) and equivalents thereof. In addition, the first electrode 1014 may be formed of one transparent conductive oxide selected from indium tin oxide (ITO), indium zinc oxide (IZO), zinc oxide, tin oxide (SnO₂), indium oxide (In₂O₃) and equivalents thereof.

The second electrode 1015 is also formed in the shape of a thin layer having a certain thickness and has the opposite polarity to that of the first electrode 1014. In the other words, if the first electrode 1014 is a source electrode, the second electrode 1015 may be used as a drain electrode (or a source electrode). The second electrode 1015 is electrically connected to the nanowire 1013. That is, the second electrode 1015 covers simultaneously the other end of the nanowire 1013 and inner and outer circumference surfaces of the other end so that the second electrode is electrically connected to the nanowire 1013. In addition, the second electrode 1015 may be formed as a metal layer formed of one selected from aluminum (Al), tin (Sn), tungsten (W), aurum (Au), chrome (Cr), molybdenum (Mo), palladium (Pd), platinum (Pt), nickel (Ni), titanium (Ti) and equivalents thereof. In addition, the second electrode 1015 may be formed of one transparent conductive oxide selected from indium tin oxide (ITO), indium zinc oxide (IZO), zinc oxide, tin oxide (SnO₂), indium oxide (In₂O₃) and equivalents thereof.

Meanwhile, if the work function of the first electrode 1014 does not differ from that of the second electrode 1015, it is difficult to emit the light from the nanowire 1013. As one example, the first electrode 1014 may be formed of one selected from indium tin oxide (ITO), indium zinc oxide (IZO), zinc oxide, tin oxide (SnO₂), indium oxide (In₂O₃) having a relatively high work function, and equivalent thereof. The work function of the above materials is approximately 4.9 eV which is a relatively high work function.

At this time, the second electrode 312 may be formed of one selected from aluminum having a relatively low work function, and equivalent thereof. The work function of the above materials is approximately 4.1 eV which is a relatively low work function.

Moreover, in case where the material such as indium tin oxide (ITO), indium zinc oxide (IZO), zinc oxide, tin oxide (SnO₂), indium oxide (In₂O₃) and the like is used for forming simultaneously the first electrode 1014 and the second cathode 1015, in order to generate a difference of the work function between the first electrode 1014 and the second electrode 312, magnesium or aluminum may be deposited in advance before forming any one electrode.

In addition, the first electrode 1014 is flush with the second electrode 1015 and the first electrode and the second electrode are spaced apart from each other in the horizontal direction so that the horizontal-type nanowire light emitting transistor LED T1 is realized. Furthermore, in case of the above horizontal-type nanowire light emitting transistor LED T1, a bidirectional light emitting structure by which the light is emitted in the upward direction and the downward direction can be obtained, and by forming the lower gate electrode 1011 as an opaque reflective metal layer or forming additionally an opaque reflective metal layer on the nanowire light emitting transistor, the light emitting direction can be adjusted to emit the light in only one direction.

As shown in FIG. 13c, a separate light shielding member 1016 may be further formed on or below a bottom gate transistor 1010a (a switching transistor) according to yet another embodiment of the present invention. As described above, if the first electrode 1014 and the second electrode 1015 having the different work functions are employed, the nanowire 1013 can emit the light. Due to the light shielding member 1016, however, it is possible to prevent the light emitted from the nanowire 1013 being radiated to an outside of the display device. In such switching transistor, of course, if the first electrode and the second electrode having the same work function are employed, it is possible to restrain the light from being emitted as above.

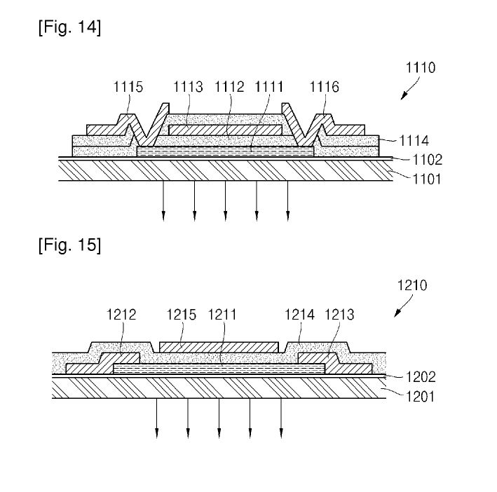

FIG. 14 is a cross-sectional view illustrating a top gate nanowire light emitting transistor according to yet another embodiment of the present invention.

As shown in FIG. 14, a top gate nanowire light emitting transistor 1110 includes a nanowire 1111 formed on a buffer layer 1102 of a substrate 1101; a gate insulating layer 1112 covering the nanowire 1111; a gate electrode 1113 formed on the gate insulating layer 1112 corresponding to the nanowire 1111; an interlayer dielectric 1114 covering the gate insulating electrode 1113 and the gate insulating layer 1112 corresponding to a periphery the gate electrode 1113; a first electrode 1115 penetrating the interlayer dielectric 1114 and connected to one end of the nanowire 1111 via the penetrating portion thereof; and a second electrode 1116 penetrating the interlayer dielectric 1114 and connected to the other end of the nanowire 1111 via the penetrating portion thereof.

Here, the nanowire 1111 is formed of the above-illustrated material having a light emitting function as well as a function of a semiconductor, and the first electrode 1115 and the second electrode 1116 may be formed of the above-illustrated material. Of course, in order to enable the nanowire 111 to have a light emitting function as well as a function of a semiconductor , the first electrode 1114 and the second electrode 1115 are formed of materials, respectively, whose the work functions differ from each other.

FIG. 15 is a cross-sectional view illustrating a top gate nanowire light emitting transistor according to further another embodiment of the present invention.

As shown in FIG. 15, a top gate nanowire light emitting transistor 1210 includes a nanowire 1211 formed on a buffer layer 1202 of a substrate 1201; a first electrode 1212 connected to one end of the nanowire 1211; a second electrode 1212 connected to the other end of the nanowire 1211; a gate insulating layer 1214 covering the nanowire 1211, the first electrode 1212 and the second electrode 1212; and a gate electrode 1215 formed on the gate insulating layer 1214 corresponding to the nanowire 1211.

Here, the nanowire 1211 is formed of the above-illustrated material having a light emitting function as well as a function of a semiconductor, and the first electrode 1212 and the second electrode 1213 may be formed of the above-illustrated material. Of course, in order to enable the nanowire 1211 to have a light emitting function as well as a function of a semiconductor, the first electrode 1212 and the second electrode 1213 are formed of materials, respectively, whose the work functions differ from each other.

On the other hand, the switching transistor T2 shown in FIG. 12 has a structure which is virtually the same as those of the nanowire light emitting transistors 1010, 1110 and 1210 described above. Except that the first electrode and the second electrode are formed of the same material (i. e, the first electrode and the second electrode are formed of materials having the same work function) so as to prevent the nanowire of the switching transistor T2 from emitting the light, the switching transistor has a structure which is the same as those of the nanowire light emitting transistors 1010, 1110 and 1210.

As one example, the first electrode and the second electrode in the switching transistor T2 may be formed of one metal selected from aluminum (Al), tin (Sn), tungsten (W), aurum (Au), chrome (Cr), molybdenum (Mo), palladium (Pd), platinum (Pt), nickel (Ni), titanium (Ti) and equivalents thereof. In addition, the first electrode and the second electrode may be formed of one transparent conductive oxide selected from indium tin oxide (ITO), indium zinc oxide (IZO), zinc oxide, tin oxide (SnO₂), indium oxide (In₂O₃) and equivalents thereof.

As described above, the first electrode and the second electrode are formed of the materials having the same work function so as to prevent the nanowire disposed between and electrically connected to the first electrode and the second electrode from emitting the light. For example, if the first electrode is formed of aluminum, the second electrode is also formed of aluminum. In addition, if the first electrode is formed of indium tin oxide, the second electrode is also formed of indium tin oxide.

Undoubtedly, the switching transistor T2 shown in FIG. 12 may have the structure which is the exact same as those of the nanowire light emitting transistors 1010, 1110 and 1210. In other words, the first electrode and the second electrode having the different work functions can be employed. Like the nanowire light emitting transistors 1010, 1110 and 1210, at this time, the switching transistor T2 emits the prescribed colored-light. By forming a separate light-shielding member on or below the switching transistor T2, it is possible to prevent the light emitted from the nanowire 513 from being radiated to an outside (see FIG. 13c)

The above description illustrates only one example for implementing the light emitting display device having a nanowire according to the present invention, the present invention is not limited to the above embodiment and one skilled in the art may modify the present invention without departing from the scope of the present invention claimed in the accompanying claims.

1. A light emitting display device, comprising;
a light emitting element electrically connected to a first power line;
a driving transistor electrically connected to the light emitting element and a second power line;
a capacitor electrically connected to the driving transistor, the second power line and a data line; and
a switching transistor electrically connected among the driving transistor, the data line, and a scanning line,
wherein the light emitting element is made from a nanowire.

2. The light emitting display device of claim 1, wherein the light emitting element further comprises
a first electrode covering one end of the nanowire and inner circumference and outer circumference surfaces of the one end and electrically connected to the first power line; and
a second electrode covering the other end of the nanowire and inner circumference and outer circumference surfaces of the other end and electrically connected to the second power line,
wherein the first electrode has the work function which differs from that of the second electrode.

3. The light emitting display device of claim 2, wherein the first electrode is flush with the second electrode and spaced apart from the second electrode in the horizontal direction.

4. The light emitting display device of claim 1, wherein the light emitting element further comprises
a first electrode formed below the nanowire; and
a second electrode formed above the nanowire,
wherein the work function of the first electrode differs from that of the second electrode.

5. The light emitting display device of claim 4, wherein the first electrode is not flush with the second electrode and spaced apart from the second electrode in the vertical direction.

6. The light emitting display device of claim 1, wherein the light emitting element comprises
at least one first electrode; and
a second electrode spaced apart from the first electrode in the horizontal direction and surrounding at least three side surfaces of the first electrode,
wherein the nanowire is formed between the first electrode and the second electrode, and
wherein the work function of the first electrode differs from that of the second electrode.

7. The light emitting display device of claim 6, further comprising a color filter formed on or below the light emitting element.

8. The light emitting display device of claim 1, wherein the driving transistor or the switching transistor comprises
a gate electrode;
a gate insulating layer covering the gate electrode;
a second nanowire formed on the gate insulating layer corresponding to the gate electrode;
a first electrode connected to one end of the second nanowire; and
a second electrode connected to the other end of the second nanowire.

9. The light emitting display device of claim 1, wherein the driving transistor or the switching transistor comprises
a second nanowire;
a gate insulating layer covering the second nanowire;
a gate electrode formed on the gate insulating layer covering the second nanowire;
an interlayer dielectric covering the gate electrode and the gate insulating layer corresponding to a periphery the gate electrode;
a first electrode penetrating the interlayer dielectric and connected to one end of the second nanowire; and
a second electrode penetrating the interlayer dielectric and connected to the other end of the second nanowire.

10. The light emitting display device of claim 1, wherein the driving transistor or the switching transistor comprises
a second nanowire;
a first electrode connected to one end of the second nanowire;
a second electrode connected to the other end of the second nanowire;
a gate insulating layer covering the second nanowire, the first electrode and the second electrode; and
a gate electrode formed on the gate insulating layer corresponding to the second nanowire.

11. The light emitting display device of claim 1, wherein the capacitor comprises
a second nanowire formed on a substrate;
an insulating layer surrounding the second nanowire;
a first electrode surrounding the insulating layer; and
a second electrode connected to the second nanowire exposed through the insulating layer.

12. The light emitting display device of claim 11, wherein the substrate has a recess formed on an area thereof corresponding to the insulator.

13. The light emitting display device of claim 11, wherein the capacitor comprises
a second nanowire;
a first electrode connected to the second nanowire;
an insulating layer covering the second nanowire; and
a second electrode formed on the insulating layer corresponding to the second nanowire.

14. The light emitting display device of claim 11, wherein the nanowire is formed of mixture or compound of CaS:Eu, ZnS:Sm, ZnS:Mn, Y₂O₂S:Eu, Y₂O₂S:Eu,Bi, Gd₂O₃:Eu, (Sr,Ca,Ba,Mg)P₂O₇:Eu,Mn, CaLa₂S₄:Ce, SrY₂S₄:Eu, (Ca,Sr)S:Eu, SrS:Eu, Y₂O₃:Eu, YVO₄:Eu,Bi, ZnS:Tb, ZnS:Ce,Cl, ZnS:Cu,Al, Gd₂O₂S:Tb, Gd₂O₃:Tb,Zn, Y₂O₃:Tb,Zn, SrGa₂S₄:Eu, Y₂SiO₅:Tb, Y₂Si₂O₇:Tb, Y₂O₂S:Tb, ZnO:Ag, ZnO:Cu,Ga, CdS:Mn, BaMgAl₁₀O₁₇:Eu,Mn, (Sr,Ca,Ba)(Al,Ga)2S₄:Eu, Ca₈Mg(SiO₄)4Cl₂:Eu,Mn, YBO₃:Ce,Tb, Ba₂SiO₄:Eu, (Ba,Sr)2SiO₄:Eu, Ba₂(Mg,Zn)Si₂O₇:Eu, (Ba,Sr)Al₂O₄:Eu, Sr₂Si₃O₈,2SrCl₂:Eu, SrS:Ce, ZnS:Tm, ZnS:Ag,Cl, ZnS:Te, Zn₂SiO₄:Mn, YSiO₅:Ce, (Sr,Mg,Ca)10(PO₄)6Cl₂:Eu, BaMgAl₁₀O₁₇:Eu, BaMg₂Al₁₆O₂₇:Eu, YAG (yttrium, alumium, garnet) or mixture or compound utilizing CaxSrx-1Al₂O₃:Eu+2 obtained by synthesizing CaAl₂O₃ and SrAl₂O₃, or any one selected from the group consisting of ZnO, In₂O₃, SnO₂, SiGe, GaN, InP, InAs, Ge, GaP, GaAs, GaAs/P, InAs/P, ZnS, ZnSe, CdS, CdSe or mixture or compound thereof.

15. The light emitting display device of claim 8, wherein the second nanowire is formed of any one selected from the group consisting of ZnO, In₂O₃, SnO₂, SiGe, GaN, InP, InAs, Ge, GaP, GaAs, GaAs/P, InAs/P, ZnS, ZnSe, CdS, CdSe or mixture or compound thereof.

16. The light emitting display device of claim 14, wherein the nanowire further contains a dopant which is any one selected from the group consisting of Ce, Tm, Ag, Cl, Te, Mn, Eu, Bi, Tb, Cu, Zn, Ga or mixture or compound thereof.

17. The light emitting display device of claim 15, wherein the second nanowire further contains a dopant which is any one selected from the group consisting of Ce, Tm, Ag, Cl, Te, Mn, Eu, Bi, Tb, Cu, Zn, Ga or mixture or compound thereof.

18. The light emitting display device of claim 8, wherein the first electrode and the second electrode have the same work function.

19. The light emitting display device of claim 8, further comprising a light shielding member formed on or below the driving transistor or the switching transistor.

20. A light emitting display device, comprising;
a nanowire light emitting transistor electrically connected to a first power line and a second power line;
a capacitor electrically connected to the nanowire light emitting transistor, the second power line and a data line; and
a switching transistor electrically connected to the nanowire light emitting transistor, the data line, the capacitor and a scanning line.

21. The light emitting display device of claim 20, wherein the nanowire light emitting transistor comprises
a gate electrode;
a gate insulating layer covering the gate electrode;
a nanowire formed on the gate insulating layer corresponding to the gate electrode;
a first electrode connected to one end of the nanowire; and
a first electrode connected to the other end of the nanowire,
wherein a work function of the first electrode differs from that of the second electrode.

22. The light emitting display device of claim 20, wherein the nanowire light emitting transistor comprises
a nanowire;
a gate insulating layer covering the nanowire;
a gate electrode formed on the gate insulating layer corresponding to the nanaowire;
an interlayer dielectric covering the gate electrode and the gate insulating layer corresponding to a periphery the gate electrode;
a first electrode penetrating the interlayer dielectric and connected to one end of the nanowire; and a second electrode penetrating the interlayer dielectric and connected to the other end of the nanowire,
wherein a work function of the first electrode differs from that of the second electrode.

23. The light emitting display device of claim 20, wherein the nanowire light emitting transistor comprises
a nanowire;
a first electrode connected to one end of the nanowire;
a second electrode connected to the other end of the nanowire;
a gate insulating layer covering the nanowire, the first and second electrodes; and
a gate electrode formed on the gate insulating layer corresponding to the nanowire,
wherein a work function of the first electrode differs from that of the second electrode.

24. The light emitting display device of claim 20, wherein the switching transistor comprises
a gate electrode;
a gate insulating layer covering the gate electrode;
a nanowire formed on the gate insulating layer corresponding to the gate electrode;
a first electrode connected to one end of the nanowire; and
a second electrode connected to the other end of the nanowire.

25. The light emitting display device of claim 20, wherein the switching transistor comprises
a nanowire;
a gate insulating layer covering the nanowire;
a gate electrode formed on the gate insulating layer corresponding to the nanowire;
an interlayer dielectric covering the gate electrode and the gate insulating layer corresponding to a periphery the gate electrode;
a first electrode penetrating the interlayer dielectric and connected to one end of the nanowire; and
a second electrode penetrating the interlayer dielectric and connected to the other end of the nanowire.

26. The light emitting display device of claim 20, wherein the switching transistor comprises
a nanowire;
a first electrode connected to one end of the nanowire;
a second electrode connected on the other end of the nanowire;
a gate insulating layer covering the nanowire, the first electrode and the second electrode; and
a gate electrode formed on the gate insulating layer corresponding to the nanowire.

27. The light emitting display device of claim 20, wherein the capacitor comprises
a nanowire formed on the substrate;
an insulating layer surrounding the nanowire; a first electrode surrounding the insulating layer; and
a second electrode connected to the nanowire exposed through the insulating layer.

28. The light emitting display device of claim 27, wherein the substrate has a recess formed on an area thereof corresponding to the insulator.

29. The light emitting display device of claim 20, wherein the capacitor comprises
a nanowire;
a first electrode connected to the nanowire;
an insulating layer covering the nanowire; and
a second electrode formed on the insulating layer corresponding to the nanowire.

30. The light emitting display device of claim 21, wherein the gate electrode is formed of transparent conductive oxide or opaque metal.

31. The light emitting display device of claim 21, wherein the nanowire is formed of mixture or compound of CaS:Eu, ZnS:Sm, ZnS:Mn, Y₂O₂S:Eu, Y₂O₂S:Eu,Bi, Gd₂O₃:Eu, (Sr,Ca,Ba,Mg)P₂O₇:Eu,Mn, CaLa₂S₄:Ce, SrY₂S₄:Eu, (Ca,Sr)S:Eu, SrS:Eu, Y₂O₃:Eu, YVO₄:Eu,Bi, ZnS:Tb, ZnS:Ce,Cl, ZnS:Cu,Al, Gd₂O₂S:Tb, Gd₂O₃:Tb,Zn, Y₂O₃:Tb,Zn, SrGa₂S₄:Eu, Y₂SiO₅:Tb, Y₂Si₂O₇:Tb, Y₂O₂S:Tb, ZnO:Ag, ZnO:Cu,Ga, CdS:Mn, BaMgAl₁₀O₁₇:Eu,Mn, (Sr,Ca,Ba)(Al,Ga)2S₄:Eu, Ca₈Mg(SiO₄)4Cl₂:Eu,Mn, YBO₃:Ce,Tb, Ba₂SiO₄:Eu, (Ba,Sr)2SiO₄:Eu, Ba₂(Mg,Zn)Si₂O₇:Eu, (Ba,Sr)Al₂O₄:Eu, Sr₂Si₃O₈,2SrCl₂:Eu, SrS:Ce, ZnS:Tm, ZnS:Ag,Cl, ZnS:Te, Zn₂SiO₄:Mn, YSiO₅:Ce, (Sr,Mg,Ca)10(PO₄)6Cl₂:Eu, BaMgAl₁₀O₁₇:Eu, BaMg₂Al₁₆O₂₇:Eu, YAG (yttrium, alumium, garnet) or mixture or compound utilizing CaxSrx-1Al₂O₃:Eu+2 obtained by synthesizing CaAl₂O₃ and SrAl₂O₃ , or any one selected from the group consisting of ZnO, In₂O₃, SnO₂, SiGe, GaN, InP, InAs, Ge, GaP, GaAs, GaAs/P, InAs/P, ZnS, ZnSe, CdS, CdSe or mixture or compound thereof.

32. The light emitting display device of claim 21, wherein the nanowire is formed of any one selected from the group consisting of ZnO, In₂O₃, SnO₂, SiGe, GaN, InP, InAs, Ge, GaP, GaAs, GaAs/P, InAs/P, ZnS, ZnSe, CdS, CdSe or mixture or compound thereof.

33. The light emitting display device of claim 31, wherein the nanowire further contains a dopant which is any one selected from the group consisting of Ce, Tm, Ag, Cl, Te, Mn, Eu, Bi, Tb, Cu, Zn, Ga or mixture or compound thereof.

34. The light emitting display device of claim 32, wherein the nanowire further contains a dopant which is any one selected from the group consisting of Ce, Tm, Ag, Cl, Te, Mn, Eu, Bi, Tb, Cu, Zn, Ga or mixture or compound thereof.

35. The light emitting display device of claim 24, wherein the first electrode and the second electrode have the same work function.

36. The light emitting display device of claim 24, further comprising a light shielding member formed on or below the switching transistor.

37. The light emitting display device of claim 21, further comprising a color filter formed on or below the nanowire light emitting transistor.
